(19) United States
(12) Patent Application Publication
(10) Pub. No.: US 2008/0111211 A1
(43) Pub. Date: May 15, 2008

(54) On-chip capacitors for addressing power supply voltage drops

(76) Inventor: Pratheep A. Nair, Bangalore (IN)

Correspondence Address: MCANDREWS HELD & MALLOY, LTD, 500 WEST MADISON STREET, SUITE 3400, CHICAGO, IL, 60661, US

(21) Appl. No.: 11/598,326

(22) Filed: Nov. 13, 2006

(51) Int. Cl. H01L 27/00; G06F 17/50

(52) U.S. Cl. 257/532; 716/1; 257/E27.001

(57) ABSTRACT

Herein described are at least a layout of an integrated circuit chip that is resistant to the negative effects of IR power supply voltage drops and a method of implementing the integrated circuit chip. The integrated circuit chip layout comprises one or more capacitors positioned in between adjacent functional blocks. The one or more capacitors provide a charge reservoir for use by functional blocks that are affected by IR power supply voltage drops. The method for implementing the integrated circuit chip comprises positioning one or more capacitors in between adjacent functional blocks and connecting one end of each of the one or more capacitors to a power supply rail while connecting the other end to a ground rail. Each of the one or more capacitors may be implemented using a polysilicon layer and an N-well layer.

### CROSS-REFERENCE TO RELATED APPLICATIONS/INCORPORATION BY REFERENCE

[Not Applicable]

### FEDERALLY SPONSORED RESEARCH OR DEVELOPMENT

[Not Applicable]

### [MICROFICHE/COPYRIGHT REFERENCE]

[Not Applicable]

### BACKGROUND OF THE INVENTION

With improvements in technology, the circuit density and operational speeds of integrated circuit devices have increased. As circuits operate with high frequencies, the power consumption of an integrated circuit device may be high. Furthermore, as the dimensions of integrated circuits have decreased, the power supply voltages of such integrated circuits have correspondingly decreased. As a result, corresponding noise margins have decreased. As a consequence, a situation that reduces the power supply voltage may have a serious effect on the performance of an integrated circuit device. Such a situation may occur when the integrated circuit device encounters an “IR power supply voltage drop”. One or more of these “IR power supply voltage drops” may present itself at various points within an integrated circuit device. Static IR power supply voltage drops may occur because of inherent resistances of the one or more conductors used to supply current throughout the integrated circuit device. These static IR voltage drops may occur along any conductive path between a power supply input pin at the periphery of an integrated circuit device and a particular power supply rail of a functional block within the integrated circuit device. Furthermore, when implementing integrated circuits, dynamic IR power supply voltage drops may occur anywhere transistors are switched. A dynamic IR voltage drop may occur when power supply current, destined for a particular functional block, passes through one or more other functional blocks that are operating at high frequencies. Such dynamic and static IR power supply voltage drops may have a significant negative impact on the performance of the entire functional block.

The limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Various aspects of the invention provide a method for minimizing voltage drops provided by one or more power supply rails within an integrated circuit chip, as substantially shown in and/or described in connection with at least one of the following figures, as set forth more completely in the claims.

These and other advantages, aspects, and novel features of the present invention, as well as details of illustrated embodiments, thereof, will be more fully understood from the following description and drawings.

### BRIEF DESCRIPTION OF THE DRAWINGS

FIG. 1 is a typical layout of an integrated circuit chip in which a method of minimizing power supply voltage drops may be implemented, in accordance with an embodiment of the invention.

FIG. 2 is a more magnified view of a typical layout of an integrated circuit chip, in comparison to FIG. 1, illustrating the usable area where an on-chip capacitor may be incorporated between adjacent functional blocks, in accordance with an embodiment of the invention.

FIG. 3 is a relational block diagram depicting the usable area between two functional blocks in an integrated circuit layout, in accordance with an embodiment of the invention.

FIG. 4 is a block diagram of a portion of a functional block of an integrated circuit layout showing the power supply rails and ground rails, in accordance with an embodiment of the invention.

FIG. 5 is a diagram of an implementation of an on-chip capacitor within an integrated circuit chip, in accordance with an embodiment of the invention.

FIG. 6 is a block diagram illustrating one or more on-chip capacitors located between functional blocks of a section of an integrated circuit chip, in accordance with an embodiment of the invention.

FIG. 7 is an operational flow diagram describing a method for implementing an integrated circuit chip which is resistant to power supply voltage drops, in accordance with an embodiment of the invention.

### DETAILED DESCRIPTION OF THE INVENTION

Various aspects of the invention can be found in an integrated circuit chip that is resistant to power supply voltage drops. Various aspects of the invention employ one or more on-chip capacitors for addressing such voltage drops within an integrated circuit chip. The on-chip capacitors may be implemented in a typically unused area adjacent to a functional block located within the integrated circuit chip. The on-chip capacitors may be implemented on-chip without suffering any integrated circuit area penalty. In a representative embodiment, the on-chip capacitors may be implemented substantially toward the center of the integrated circuit chip because the additive effects of one or more power supply voltage drops may be more pronounced furthest from the periphery of the integrated circuit chip. As current travels from the periphery of an integrated circuit chip to the center, it may be more likely to be affected by dynamic and/or static power supply voltage drops as it passes through one or more integrated circuit functional blocks. Typically, the voltage provided by one or more power supply rails of the integrated circuit chip originates from an external source that is connected to the integrated circuit chip. The voltage may be supplied using a conductive pin or conductive contact located at the periphery of the integrated circuit chip.

Furthermore, various aspects of the invention can be found in a method of designing an integrated circuit device that is resistant to power supply voltage drops. In a representative embodiment, the method comprises implementing one or more on-chip capacitors in areas between functional circuit blocks of the integrated circuit chip. The method further comprises connecting the on-chip capacitors to a power supply rail and a ground rail of the integrated circuit chip. In a representative embodiment, CMOS technology is used to implement the integrated circuit chip. The one or more on-chip capacitors provide a charge reservoir for functional blocks that are affected by power supply voltage drops.

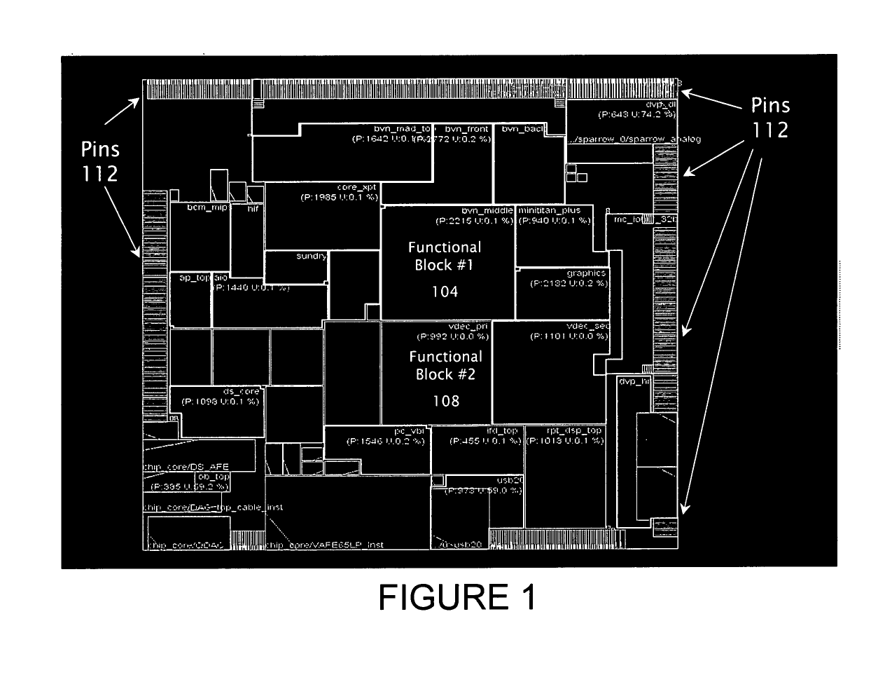

FIG. 1 is a typical layout of an integrated circuit chip in which a method of minimizing power supply voltage drops may be implemented, in accordance with an embodiment of the invention. The integrated circuit chip comprises a plurality of functional blocks and conductive pins 112. FIG. 1 illustrates only functional block #1 104 and functional block #2 108, for example. Although functional block #1 104 and functional block #2 108 are rectangular in shape, a functional block may be implemented in other shapes, as illustrated. Between the borders of functional block #1 104 and functional block #2 108, there is an area which may be used to incorporate one or more on-chip capacitors. These one or more on-chip capacitors may be used to provide a charge reservoir for the functional blocks 104, 108 such that power supply voltage drops may be mitigated. The charge or energy stored in the one or more on-chip capacitors may be used to supplement any reduction in current resulting from static or dynamic IR power supply voltage drops.

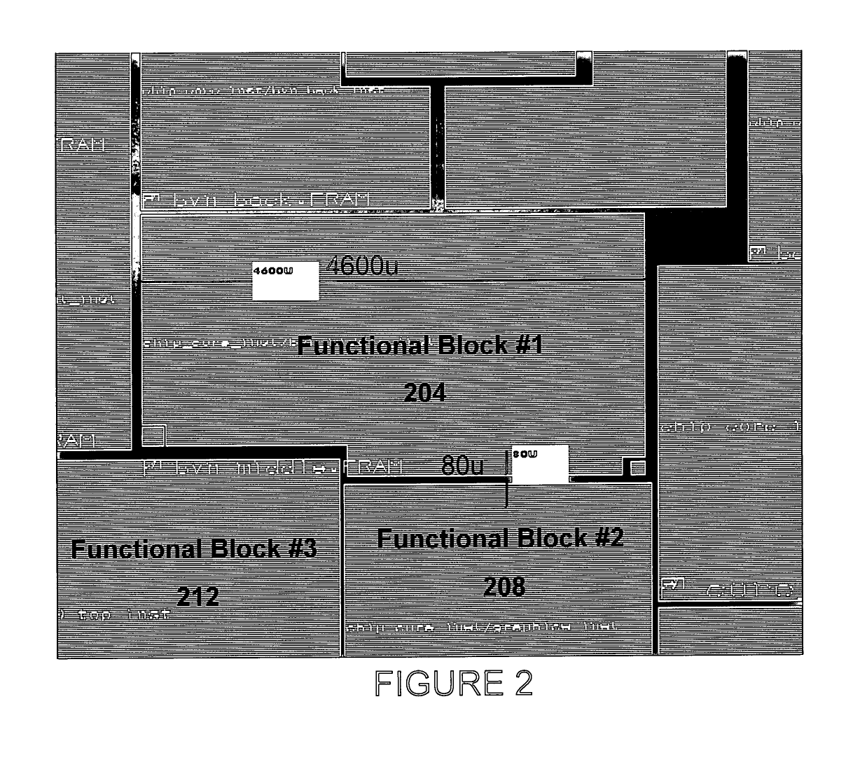

FIG. 2 is a more magnified view of a typical layout of an integrated circuit chip, in comparison to FIG. 1, illustrating the usable area where an on-chip capacitor may be incorporated between adjacent functional blocks, in accordance with an embodiment of the invention. The typical layout comprises a first functional block 204, a second functional block 208, and a third functional block 212. Only three functional blocks 204, 208, 212 are shown for practical purposes. As indicated in FIG. 2, the functional blocks 204, 208, 212 are separated by areas of silicon, in which, one or more on-chip capacitors may be implemented. For example, there exists a separation of 80 microns between functional block #1 204 and functional block #2 208 in the illustrative representative embodiment. In comparison, the width of functional block #1 204, as indicated in FIG. 1, is 4600 microns. This otherwise unused area may be used to implement one or more on-chip capacitors. The one or more on-chip capacitors may be used to reduce or mitigate one or more IR power supply voltage drops occurring within the interior of an integrated circuit chip. The one or more on-chip capacitors may be connected to power supply rails and ground rails. One or more power supply rails and ground rails may be supplied to each of one or more rows of standard cells that are implemented in each of the functional blocks 204, 208, 212.

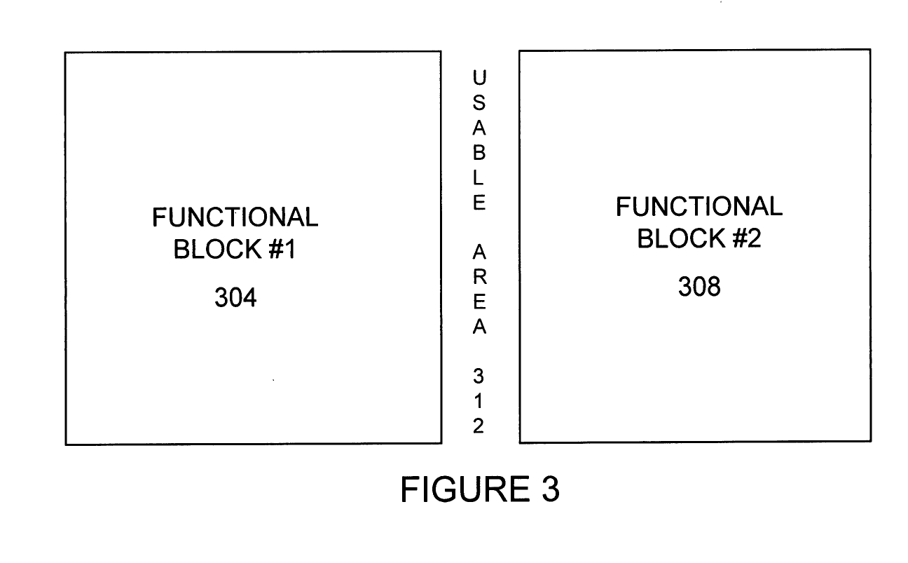

FIG. 3 is a relational block diagram depicting the usable area 312 between two functional blocks 304, 308 in an integrated circuit layout, in accordance with an embodiment of the invention. The distance between the two functional blocks 304, 308 may be approximately 80 microns, such that an on-chip capacitor may be implemented between the two functional blocks 304, 308. Each of the two functional blocks 304, 308 may comprise a plurality of standard cells arranged in a plurality of rows.

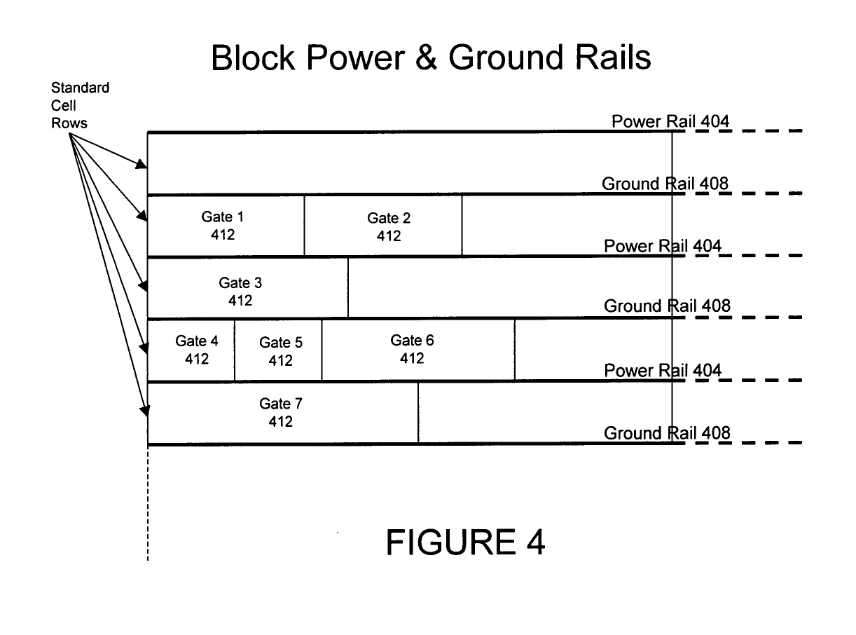

FIG. 4 is a block diagram of a portion of a functional block of an integrated circuit layout showing the power supply rails 404 and ground rails 408, in accordance with an embodiment of the invention. Also shown in FIG. 4 is a plurality of gates 412 implemented over multiple standard cell rows. Each of the gates 412 comprises a plurality of standard cells. The representative embodiment shown in FIG. 4 may correspond to the first functional block shown in connection with FIG. 1. Each standard cell row is connected to its respective power supply rail and ground rail. The power supply and ground rail supply power to the plurality of standard cells in each standard cell row of a functional block. The power supply rail may provide a specific voltage required for proper operation of the plurality of standard cells.

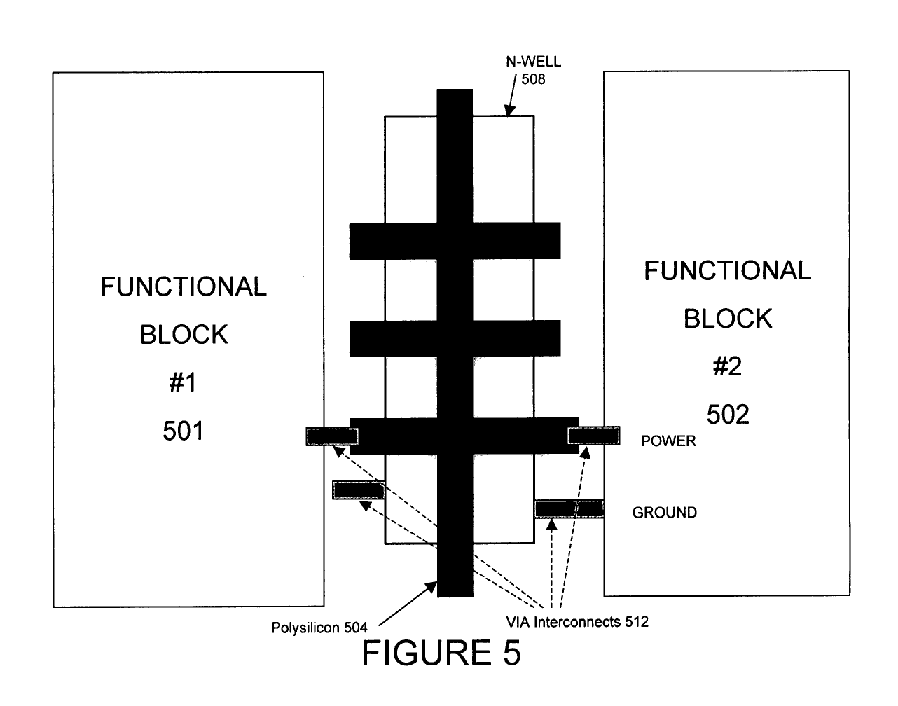

FIG. 5 is a diagram of an implementation of an on-chip capacitor within an integrated circuit chip, in accordance with an embodiment of the invention. As illustrated, the on-chip capacitor is located between functional block #1 501 and functional block #2 502. The on-chip capacitor comprises a polysilicon layer 504 and an N-well layer 508. In the representative embodiment shown, the polysilicon layer 504 of the on-chip capacitor is connected to power supply rails of functional block #1 501 and functional block #2 502. In a representative embodiment the power supply rails are implemented using one or more metal layers. In the representative embodiment shown, the N-well layer 508 of the on-chip capacitor is connected to the ground rails of functional block #1 501 and functional block #2 502. The power supply and the ground rails are connected to the on-chip capacitor using via interconnects 512.

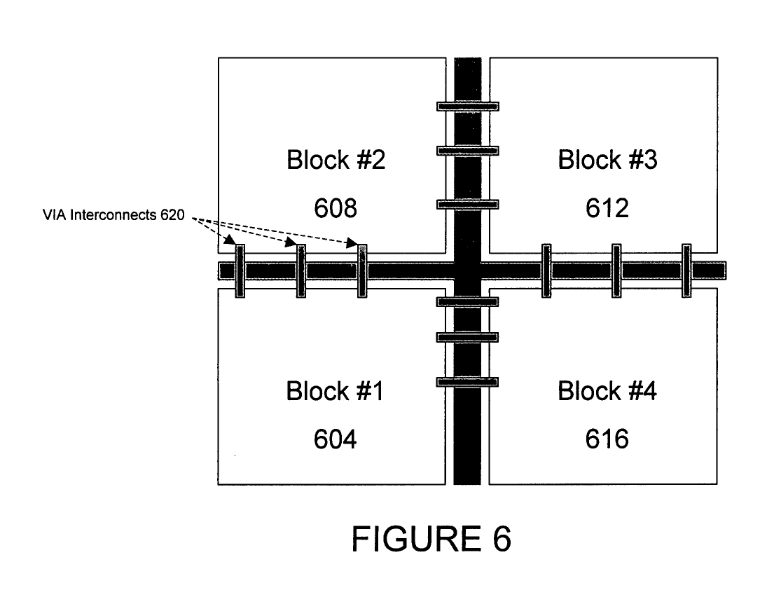

FIG. 6 is a block diagram illustrating one or more on-chip capacitors that are located between functional blocks of a section of an integrated circuit chip, in accordance with an embodiment of the invention. As illustrated, the on-chip capacitors may be located in normally unused areas of an integrated circuit chip. The section shown comprises four functional blocks 604, 608, 612, 616. FIG. 6 illustrates a number of via interconnects 620 used to connect power supply rails to a capacitor. Each of the via interconnects 620 provides the locations of the on-chip capacitors between adjacent functional blocks. The on-chip capacitors may be implemented in these normally unused areas by way of using polysilicon and N-well layers of the integrated circuit chip.

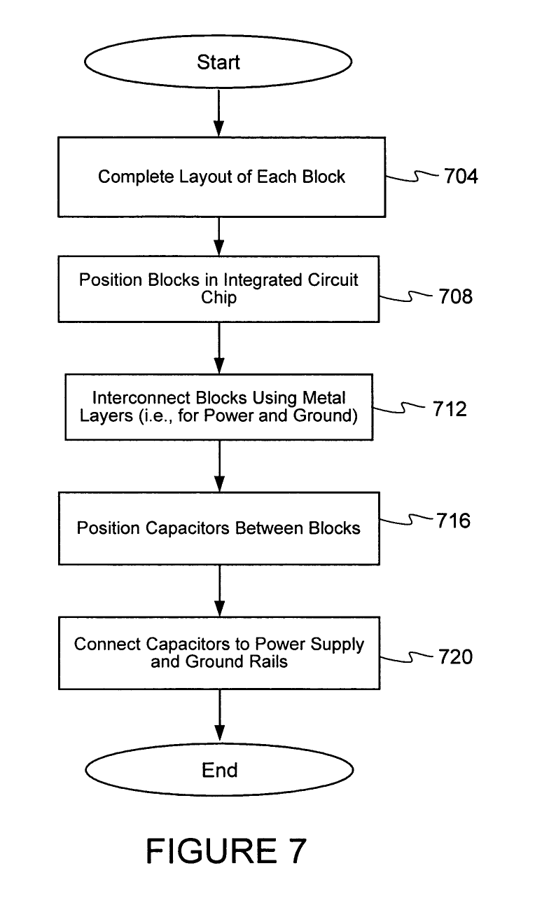

FIG. 7 is an operational flow diagram describing a method for implementing an integrated circuit chip that is resistant to power supply voltage drops, in accordance with an embodiment of the invention. At step 704, a layout is designed for each functional block of the integrated circuit chip. Next, at step 708, the functional blocks are positioned or appropriately placed within the integrated circuit chip. Thereafter, the functional blocks are interconnected using metal layers at step 712. The metal layers may comprise power supply rails or ground rails, for example. At step 716, one or more capacitors are positioned between functional blocks. The metal layers may be connected to one or more capacitors using via interconnects, for example. Finally, at step 720, one end of each of the one or more capacitors may be connected to a power supply rail while the other end of the capacitor may be connected to a ground rail. The ends of each capacitor may be connected to power supply rails and ground rails, by using via interconnects, for example.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiments disclosed, but that the invention will include all embodiments falling within the scope of the appended claims.

What is claimed is:

1. An integrated circuit device comprising:
one or more on-chip capacitors used for minimizing power supply voltage drops within said integrated circuit device, said power supply voltage drops reducing the voltage supplied to one or more functional blocks of said integrated circuit device.

2. The integrated circuit device of claim 1 wherein said one or more on-chip capacitors are connected across a power rail and a ground rail, said power rail and said ground rail communicatively coupled between adjacent functional blocks.

3. The integrated circuit device of claim 2 wherein said power rail and said ground rail is used to deliver power to one or more gates within each of said one or more functional blocks.

4. The integrated circuit device of claim 3 wherein each of said one or more gates is comprised of one or more standard cells.

5. The integrated circuit device of claim 2 wherein said power is delivered to said one or more functional blocks of said integrated circuit device using a conductive pin located at the periphery of said integrated circuit device, said conductive pin connected to said power rail.

6. The integrated circuit device of claim 1 wherein said one or more on-chip capacitors and said one or more functional blocks are implemented using CMOS technology.

7. The integrated circuit device of claim 6 wherein said one or more on-chip capacitors are designed using a polysilicon layer and an N-well layer.

8. A method for designing a layout of an integrated circuit chip comprising:
placing an on-chip capacitor in areas between adjacent functional blocks of said integrated circuit chip to reduce the effects of static and dynamic IR power supply voltage drops; and
connecting a first end of said on-chip capacitor to a power supply rail and a second end of said on-chip capacitor to a ground rail, said power supply rail used to power said adjacent functional blocks in said integrated circuit device.

9. The method of claim 8 wherein said on-chip capacitor stores energy to compensate for said static and dynamic IR power supply voltage drops within said integrated circuit chip.

10. The method of claim 8 wherein said placing said on-chip capacitor occurs without suffering any area penalty to said layout of said integrated circuit chip.

11. The method of claim 8 wherein said power supply rail is supplied by way of an external source connected to a conductive contact located at the periphery of said integrated circuit chip.

12. The method of claim 8 wherein said layout is designed using CMOS technology.

13. An integrated circuit chip comprising:
at least one on-chip capacitor used for alleviating voltage drops affecting a power supply rail, said power supply rail providing power to one or more functional blocks of said integrated circuit chip.

14. The integrated circuit chip of claim 13 wherein said at least one on-chip capacitor is connected across said power supply rail and a ground rail, said at least one on-chip capacitor located in areas between adjacent functional blocks of said one or more functional blocks.

15. The integrated circuit chip of claim 14 wherein a conductive contact located at the periphery of said integrated circuit chip is used to provide power to said power supply rail.

16. The integrated circuit chip of claim 13 wherein each of said one or more functional blocks comprises one or more gates.

17. The integrated circuit chip of claim 16 wherein each of said one or more gates comprises one or more standard cells.

18. The integrated circuit chip of claim 17 wherein said power supply rail and said ground rail are connected to each of said one or more gates of each of said one or more standard cells.

19. The integrated circuit chip of claim 17 wherein said one or more standard cells are implemented using CMOS technology.

20. The integrated circuit chip of claim 13 wherein each of said at least one on-chip capacitor is implemented using a polysilicon layer and an N-well layer.
